(19) United States
(12) Patent Application Publication
(10) Pub. No.: US 2005/0133798 A1
(43) Pub. Date: Jun. 23, 2005

(54) Nitride semiconductor template for light emitting diode and preparation thereof

(76) Inventors: Hyun-Min Jung, Seongnam-si (KR); Hae-Yong Lee, Kwangmyung-si (KR); Hyun-Min Shin, Seoul (KR); Choon-Kon Kim, Suwon-si (KR); Chang-Ho Lee, Suwon-si (KR); Jeong-Wook Lee, Suwon-si (KR); Cheol-Soo Sone, Anyang-si (KR); Jae-Hee Cho, Yongin-si (KR)

Correspondence Address: David A. Einhom, Esq.;Anderson Kill & Olick, P.C., 1251 Avenue of the Americas, New York, NY, 10020, US

(21) Appl. No.: 11/017,516

(22) Filed: Dec. 20, 2004

(30) Foreign Application Priority Data
Dec. 18, 2003 (KR) 10-2003-0093147

(51) Int. Cl. H01L 21/00; H01L 27/15; H01L 29/26; H01L 31/12; H01L 33/00

(52) U.S. Cl. 257/79; 438/22; 438/46; 257/94

(57) ABSTRACT

A nitride semiconductor template having nano-voids at an interface between a substrate having one embossed surface and a nitride semiconductor layer can be rapidly prepared by hydride vapor phase epitaxy (HVPE) growth of the nitride semiconductor layer on the embossed surface of the substrate.

### FIELD OF THE INVENTION

The present invention relates to an improved nitride semiconductor template for a light emitting diode and a method for preparing said nitride semiconductor template.

### BACKGROUND OF THE INVENTION

A light emitting diode (LED) has a common structural feature that comprises, referring FIG. 1, a template (11) consisting of a substrate and a nitride semiconductor layer (e.g., a GaN crystal layer), n-type and p-type nitride semiconductor layers (12 and 14, e.g., n-GaN and p-GaN layers, respectively), an active layer (13), and p-type and n-type electrode layers (15 and 16, respectively). The nitride semiconductor layer can be grown by a conventional method, e.g., liquid phase epitaxy (LPE), vapor phase epitaxy (VPE), metal organic chemical vapor deposition (MOCVD), molecular beam epitaxy (MBE) and hydride vapor phase epitaxy (HVPE).

In order to enhance the emittance of the laterally directed light which tends to dissipate inside a device, there has recently been reported a technique to prepare a nitride semiconductor template (11) for an LED by way of embossing the surface of a substrate and then growing a nitride semiconductor layer (11b) thereon (11a) by MOCVD (see FIG. 2).

However, the growth rate of the nitride semiconductor layer by MOCVD is low, only about several μm/hr, which causes the nitride semiconductor crystals to initially grow in a facet form on the embossed substrate. This causes the problem that the formed nitride semiconductor layer adheres too closely to the substrate, thereby generating undesirable dislocation defects and stress due to the differences in the lattice parameter and thermal expansion coefficient at the heterojunction.

### SUMMARY OF THE INVENTION

Accordingly, it is an object of the present invention to provide a high quality nitride semiconductor template for an LED having minimal dislocation defects.

It is another object of the present invention to provide a rapid and effective method for preparing said nitride semiconductor template.

In accordance with one aspect of the present invention, there is provided a nitride semiconductor template which comprises a substrate having one embossed surface and a nitride semiconductor layer formed on the embossed surface of the substrate, the substrate-nitride semiconductor layer interface having 1 to 1,000 nm-sized nano-voids.

In accordance with another aspect of the present invention, there is provided a method for preparing a nitride semiconductor template which comprises the steps of:

(a) embossing one surface of a substrate; and

(b) growing a nitride semiconductor layer on the embossed surface of the substrate by hydride vapor phase epitaxy (HVPE).

### BRIEF DESCRIPTION OF THE DRAWINGS

The above and other objects and features of the present invention will become apparent from the following description of the invention, when taken in conjunction with the accompanying drawings, which respectively show:

FIG. 1: a schematic diagram of a conventional LED;

FIG. 2: a schematic diagram of a conventional template for an LED having an embossed substrate;

FIG. 3: a scanning electron microscope (SEM) photograph of the template obtained in Example 1; and

FIG. 4: an SEM photograph of the template obtained in Comparative Example 1.

11: template

11a: substrate

11b: nitride semiconductor layer

12: n-type nitride semiconductor layer

13: active layer

14: p-type nitride semiconductor layer

15: p-type electrode layer

16: n-type electrode layer

### DETAILED DESCRIPTION OF THE INVENTION

The present invention is characterized in that a nitride semiconductor template having nano-voids formed at the interface between an embossed surface of a substrate and a nitride semiconductor layer is prepared by growing the nitride semiconductor layer on the substrate at a high growth rate of several tens to hundreds μm/hr by HVPE.

The substrate used in the present invention may be any one of conventional materials such as sapphire (Al₂O₃), ZnO, Si, SiC and GaN. The nitride semiconductor compound grown on such a substrate may be a nitride of a III-group element, representative examples thereof including nitrides of Ga, Al and In.

<Step (a)>

One surface of a substrate is embossed by a conventional method using a photoresist, e.g., by coating a photoresist on the surface of the substrate, patterning the photoresist coating layer using a conventional photolithography, hard-baking at a temperature ranging from 100 to 120° C., reactive ion-etching the substrate having a mask coating layer, and then removing the mask coating layer remaining on the substrate.

The thickness of the photoresist coated on the substrate depends on the etching depth desired in the subsequent etching process. In case 1.2 μm is the desired etching depth, the thickness of the photoresist coating layer may be about 2 μm.

The reactive ion-etching process may be performed using an etching gas such as Cl₂, BCl₃, HCl, CCl₄, SiCl₄ and a mixture thereof at a pressure of 1 to 40 mTorr.

It is preferred that the projected part of the embossed surface formed on the substrate has a lateral curvature of 0 or more.

<Step (b)>

A nitride semiconductor layer may be grown on the embossed substrate obtained in step (a) by hydride vapor phase epitaxy (HVPE) at a growth rate of 20 to 150 μm/hr, preferably 40 to 150 μm/hr, by way of bringing the vapor of the chloride of a III-group element and gaseous ammonia (NH₃) into contact with the embossed surface of the substrate maintained at a temperature ranging from 950 to 1,100° C. The vapor of the chloride of a III-group element may be generated in the HVPE reactor by placing one or more III-group elements on a vessel and introducing gaseous hydrogen chloride (HCl) thereto. The reactor chamber may be maintained at a temperature ranging from 600 to 850° C. under an ambient pressure.

If necessary, the embossed surface of the substrate obtained in step (a) may be nitrided by way of bringing a gas mixture of ammonia (NH₃) and hydrogen chloride (HCl) into contact therewith at a temperature ranging from 900 to 1,100° C. In addition, for the purpose of enhancing the nitridation, the embossed surface of the substrate may be further treated with gaseous ammonia (NH₃) before or after the above nitridation step. Such nitridation of the substrate surface may be performed in a HVPE reactor. The nitridation technique using an ammonia (NH₃)-hydrogen chloride (HCl) gas mixture is disclosed in U.S. Pat. No. 6,528,394 which is incorporated by reference in the present invention.

The rapid nitride layer growth achievable with HVPE allows the nitride semiconductor layer to grow vertically and horizontally at similar rates from a lateral side of the projected part of the embossed surface until the overgrown nitride semiconductor crystals coalescence. This growth mode is quite different from the facet growth observed when MOCVD is employed.

More importantly, the use of HVPE in the nitride layer growth on the embossed substrate surface leads to the formation of 1 to 1,000 nm-sized, preferably 1 to 500 nm-sized nano-voids at the interface between the substrate and nitride semiconductor layer grown thereon, and the surface of the overgrown nitride semiconductor layer is relatively defect-free. Thus, the overgrown nitride semiconductor layer may be planed to form a nitride semiconductor template to be used for the manufacture of an LED.

As described above, the present invention provides for the first time a high quality nitride semiconductor template having minimal dislocation defects and stress due to the presence of nano-voids at the interface between the embossed substrate and nitride semiconductor layer, which enhances the light emitting efficiency.

The following Examples and Comparative Examples are given for the purpose of illustration only, and are not intended to limit the scope of the invention.

<Preparation of Gallium Nitride Semiconductor Template>

### EXAMPLE 1

A photoresist was coated on the surface of a sapphire plate to a thickness of 2 μm, the photoresist coating layer was subjected to photolithograph and the exposed region was removed. The resulting substrate having a mask coating layer was hard-baked at 110° C. and etched to a depth of 1.2 μm using a Cl₂/BCl₃ etching gas at an electric power of 800 W under a pressure of 3 mTorr. The mask coating layer was then removed therefrom to prepare an embossed substrate having ladder-like projected parts having a lateral curvature of about 1.

The substrate with the embossed surface was installed in an HVPE reactor, and treated at 950° C. successively with gaseous ammonia, a gas mixture of ammonia and hydrogen chloride, and gaseous ammonia.

On the nitrided substrate thus obtained, gallium nitride crystals were allowed to grow at a rate of 40 μm/hr by bringing gaseous gallium chloride and gaseous ammonia into contact therewith at 1,030° C. The gallium chloride gas, generated by reacting gallium with hydrogen chloride, was introduced at a flow rate of 300 ml/min through one inlet, and gaseous ammonia, at a flow rate of 900 ml/min through another inlet. The reactor chamber was maintained at 700° C. under an ambient pressure. The growth of gallium nitride crystals was conducted for 9 minutes to obtain a 6 μm-thick gallium nitride semiconductor template.

### COMPARATIVE EXAMPLE 1

The procedure of Example 1 was repeated except that gallium nitride crystals were grown at a low rate of 3 μm/hr for 2 hrs, to obtain a 6 μm-thick gallium nitride semiconductor template.

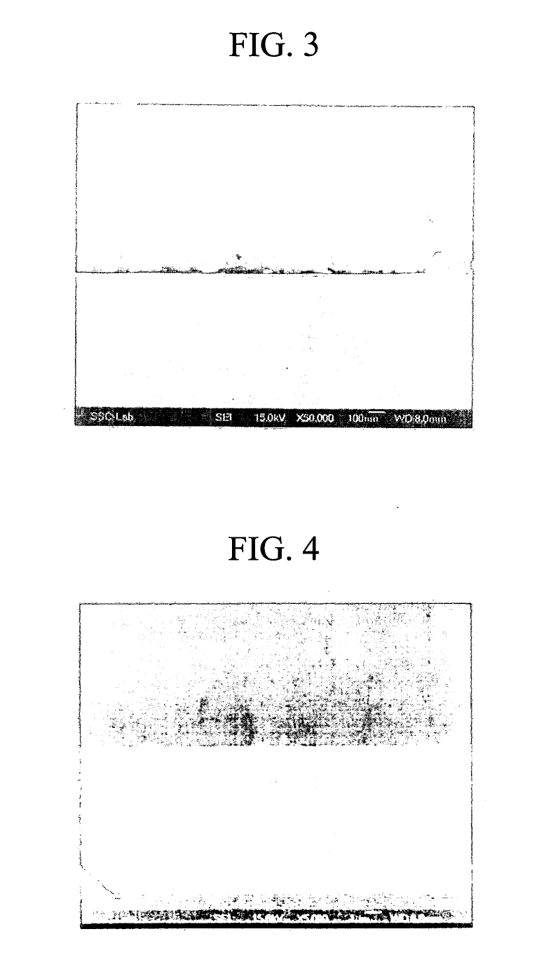

SEM photographs of the resultant templates obtained in Example 1 and Comparative Example 1 are shown in FIGS. 3 and 4, respectively. As can be seen in the figures, in case of Comparative Example 1, the gallium nitride layer formed is tightly attached to the sapphire substrate without any voids, while in Example 1, 100 nm-sized nano-voids are uniformly distributed at the interface between the sapphire substrate and gallium nitride semiconductor layer.

<Preparation of Light Emitting Diode>

### EXAMPLE 2

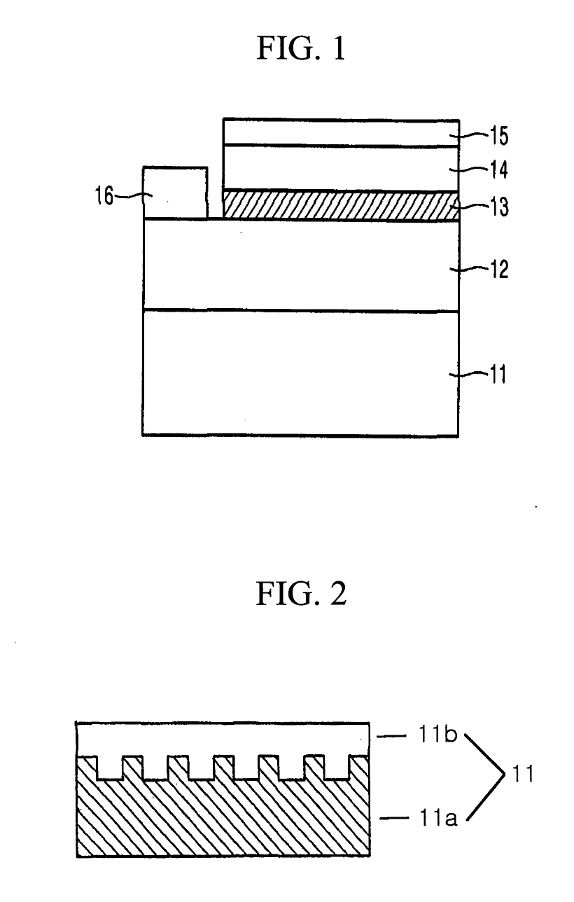

An n-GaN layer (12) (2˜3 μm) was formed on the template (11) obtained in Example 1, and an active layer (13) (0.1˜0.3 μm), p-GaN layer (14) (0.3˜0.5 μm) and p-type electrode layer (15) (300 Å) were successively formed on a part of the n-GaN layer (12) at respective growth rates of 4 μm/hr by MOCVD. Then, an n-type electrode layer (16) (300 Å) was formed on the other part of the n-GaN layer (12) at the same rate by MOCVD, to obtain a light emitting diode (LED) having the structure as shown in FIG. 1.

### COMPARATIVE EXAMPLE 2

The procedure of Example 2 was repeated using the template obtained in Comparative Example 1, to obtain an LED having a structure similar to that shown in FIG. 1.

The light generating powers of the LEDs obtained in Example 2 and Comparative Example 2 are shown in Table 1.

TABLE 1

| | Example 2 | Comparative Example 2 |
|---|---|---|
| VF at 20 mA (V) | 3.72 | 3.65 |
| PD current (au) | 1041 | 804 |

* VF: voltage forward, PD: potential difference

As shown in Table 1, the LED obtained in Example 2 exhibits higher light generating power (PD current value) by about 25% than the LED obtained in Comparative Example 2.

As described above, in accordance with the method of the present invention, a high quality nitride semiconductor template having minimal dislocation defects and less rough surface may be rapidly effectively prepared and it may be advantageously used in the manufacture of an LED.

While the invention has been described with respect to the above specific embodiments, it should be recognized that various modifications and changes may be made to the invention by those skilled in the art which also fall within the scope of the invention as defined by the appended claims.

1. A nitride semiconductor template which comprises a substrate having one embossed surface and a nitride semiconductor layer formed on the embossed surface of the substrate, the substrate-nitride semiconductor layer interface having 1 to 1,000 nm-sized nano-voids.

2. The nitride semiconductor template of claim 1, wherein the substrate is of a material selected from the group consisting of sapphire (Al₂O₃), ZnO, Si, SiC and GaN.

3. The nitride semiconductor template of claim 1, wherein the nitride semiconductor layer is composed of a nitride of Ga, Al or In.

4. A method for preparing a nitride semiconductor template which comprises the steps of:
(a) embossing one surface of a substrate; and
(b) growing a nitride semiconductor layer on the embossed surface of the substrate by hydride vapor phase epitaxy (HVPE).

5. The method of claim 4, wherein in step (a), the surface of the substrate is embossed by coating a photoresist thereon, patterning the coated photoresist layer, and hard-baking and reactive ion-etching the substrate having a mask coating layer.

6. The method of claim 4, wherein prior to step (b), the embossed surface of the substrate is nitrided by treating with a gas mixture of ammonia (NH₃) and hydrogen chloride (HCl).

7. The method of claim 6, wherein the nitridation is conducted by bringing the gas mixture of NH₃ and HCl into contact with the embossed surface of the substrate heated to a temperature ranging from 900 to 1,100° C.

8. The method of claim 4, wherein in step (b), the nitride semiconductor layer is grown on the substrate surface at a rate ranging from 20 to 150 μm/hr.

9. The method of claim 4, wherein in step (b), the nitride semiconductor layer is grown on the substrate surface at a temperature ranging from 950 to 1,100° C.

10. The method of claim 4, wherein in step (b), the nitride semiconductor layer is overgrown to form a continuous nitride semiconductor plane.

11. A light emitting diode which comprises the template of claim 1, n-type and p-type nitride semiconductor layers, an active layer, and p-type and n-type electrode layers.
